(19) United States
(12) Patent Application Publication
(10) Pub. No.: US 2016/0190397 A1
(43) Pub. Date: Jun. 30, 2016

(54) LED PACKAGE STRUCTURE AND THE MANUFACTURING METHOD OF THE SAME

(71) Applicant: UNISTARS CORPORATION, HSINCHU COUNTY (TW)

(72) Inventors: KUN-CHENG LIN, Zhubei City (TW); SHANG-YI WU, Hsinchu City (TW)

(21) Appl. No.: 14/695,062

(22) Filed: Apr. 24, 2015

(30) Foreign Application Priority Data
Dec. 29, 2014 (TW) 103146124

(51) Int. Cl. H01L 33/48; H01L 33/00; H01L 33/50; H01L 33/58; H01L 33/56

(52) U.S. Cl. CPC H01L 33/483; H01L 33/58; H01L 33/56; H01L 33/502; H01L 33/0095

(57) ABSTRACT

The present invention is related to a LED package structure, which includes a substrate having a carrier surface, a light-emitting chip disposed on the carrier surface, electrically connecting to the substrate; and a transparent protective shield disposed on the carrier surface; a hermetic receiving space is formed between the transparent protective shield and the substrate. The light-emitting chip is disposed in the hermetic receiving space. A gap is formed between the light-emitting chip and the transparent protective shield.

### FIELD OF THE INVENTION

The present invention is relating to a package structure, more particularly, to a LED package structure and the manufacturing method of the same.

### BACKGROUND OF THE INVENTION

It is necessary for the general light-emitting element to be packaged in a die as a single element and make applications to various technical fields. For example, it can be used as a display or a light apparatus. Take the LED package manufacturing process for an example, firstly a LED chip is mounted on the substrate, then the wire bonding procedure is performed to wire bond one or two electrodes of the LED chip to the electrodes of the substrate by means of conductive wires. After completing the wire bonding procedure, the encapsulation process is proceeded. In other words, the LED chip fixed on the substrate is put into the mold, and then an epoxy or silicone package material will be filled into the mold. When the epoxy package material gets hard and firm, the LED chip can be taken out of the mold. In this way, the LED chip along with the surface of the substrate for carrying the LED chip and all of the electrodes and conducting wires can be covered by the package material made of epoxy.

The conventional epoxy has the advantages of low cost, easy to manufacture, and good protection. However, the epoxy has the concerns about the insufficient heat stability and the deterioration of material properties. In view of this, in the other conventional manufacturing process of the LED package structure, by using a pure silane of better light and heat stability to replace the conventional epoxy to package the LED chip is also considered as a feasible choice, but the pure silane has the disadvantages of insufficient mechanical strength, higher unit price, and the silane material is prone or apt to aging by light illumination and causing the refraction deterioration.

Therefore, how to overcome the above problems is actually the major subject of the relating technical solutions.

### SUMMARY OF THE INVENTION

The present invention provides a light-emitting element package structure having good light and heat stability, and mechanical strength.

The present invention provides a method for manufacturing the light-emitting element package structure having good light and heat stability, and mechanical strength.

For reaching the above advantages, the present invention provides a LED package structure comprising a substrate, a light-emitting chip, and a transparent protective shield. The substrate has a carrier surface where the light-emitting chip is disposed on the carrier surface and electrically connecting to the substrate. The transparent protective shield is disposed on the carrier surface. A hermetic receiving space is formed between the transparent protective shield and the substrate. The light-emitting chip is located in the hermetic receiving space. A gap is formed between the light-emitting chip and the transparent protective shield.

In an embodiment of the present invention, the transparent protective shield comprises a supporting wall and a top portion. The supporting wall is disposed on the carrier surface and surrounding the light-emitting chip. The top portion is disposed on the supporting wall and covering the light-emitting chip.

In the embodiment of the present invention, the outer side of the surface of the top portion is plane or curved surface.

In the embodiment of the present invention, the transparent protective shield further comprises a first stack portion disposed on the top portion.

In the embodiment of the present invention, the transparent protective shield further comprising a second stack portion disposed on the first stack portion. The width of the second stack portion is smaller than the first stack portion.

In the embodiment of the present invention, the transparent protective shield further comprising a lens disposed on the first stack portion.

In the embodiment of the present invention, the transparent protective shield further comprising a lens disposed on the top portion.

In the embodiment of the present invention, the transparent protective shield is primary molding.

In the embodiment of the present invention, the available materials of the transparent protective shield are glass, acrylic, crystal, aluminium oxide, zirconium oxide.

In the embodiment of the present invention, further comprising an inert gas filled in the hermetic receiving space.

In the embodiment of the present invention, further comprising a phosphor layer coated at least on the side of the transparent protective shield facing the light-emitting chip and disposed on the surface of the transparent protective shield located above the light-emitting chip.

The present invention provides a LED package structure manufacturing method, comprising the steps of: disposing a light-emitting chip on a carrier surface of a substrate, and electrically connecting the light-emitting chip to the substrate; disposing a transparent protective shield on the carrier surface of the substrate, so as to form a hermetic receiving space between the transparent protective shield and the substrate, the light-emitting chip is disposed in the hermetic receiving space, a gap is formed between the light-emitting chip and the transparent protective shield.

In an embodiment of the present invention, the transparent protective shield comprising a supporting wall and a top portion, the step of disposing a transparent protective shield on the carrier surface of the substrate further comprising: bonding the supporting wall on the carrier surface of the substrate by means of an optical curing adhesive and surrounding the light-emitting chip, and bonding the top portion on the supporting wall by means of the optical curing adhesive and covering the light-emitting chip.

In an embodiment of the present invention, the transparent protective shield comprising a supporting wall and a top portion, the protective shield is integrally-molded, the step of disposing a transparent protective shield on the carrier surface of the substrate further comprising: bonding the supporting wall on the carrier surface of the substrate by means of an optical curing adhesive and surrounding the light-emitting chip, and the top portion covers the light-emitting chip.

The LED package structure of the present invention is using a transparent protective shield molded in advance to replace the conventional package element formed by means of encapsulation process. Different from the conventional package element, for the transparent protective shield of the present invention, the package material with better mechanical characters can be chosen. Therefore, the LED package structure of the present invention provides a better mechanical strength, and prevents material aging issue which is caused by the light illumination.

The embodiments will be described in details according to the relating figures as follows to make the technical characters and advantages of the present invention more clearly.

### BRIEF DESCRIPTION OF THE DRAWINGS

FIG. 1-FIG. 7 are cross-sectional view diagrams of an LED package structure according to a plurality of embodiments of the present invention.

FIG. 8A-FIG. 8C are process diagrams of a method for manufacturing a LED package structure according to an embodiment of the present invention.

FIG. 9A-FIG. 9B are process diagrams of a method for manufacturing a LED package structure according to another embodiment of the present invention.

### DETAILED DESCRIPTION OF THE EMBODIMENTS

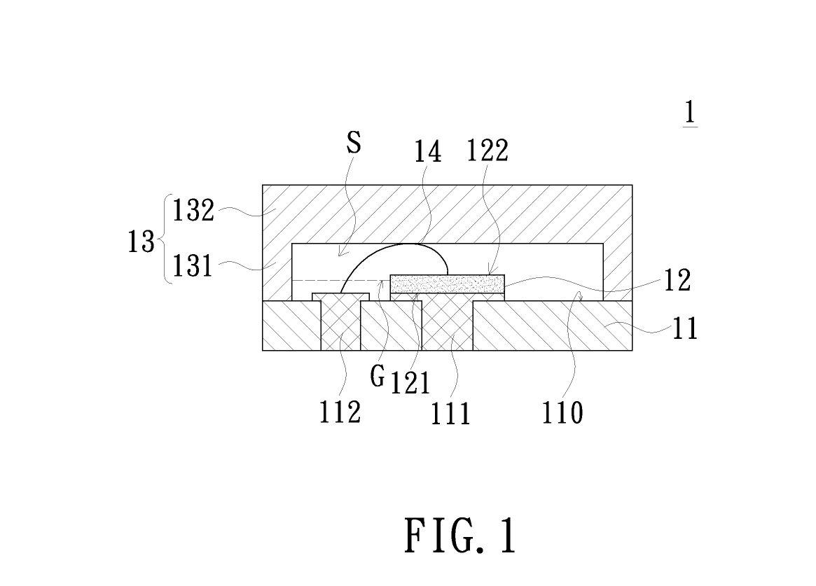

Referring to FIG. 1, an LED package structure 1 comprises a substrate 11, a light-emitting chip 12, and a transparent protective shield 13. The substrate 11 has a carrier surface 110. The light-emitting chip 12 is disposed on the carrier surface 110 of the substrate 11. The light-emitting chip 12 is electrically connected to the substrate 11 by means of an electrical conductive line 14. In this first embodiment, the light-emitting chip 12 can be, for example, a light emitting diode (LED) chip, but the present invention is not limited by this example. The transparent protective shield 13 is disposed on the carrier surface 110 of the substrate 11. A hermetic receiving space S is formed between the transparent protective shield 13 and the substrate 11. The light-emitting chip 12 is located in the hermetic receiving space S. A gap G is formed between the light-emitting chip 12 and the transparent protective shield 13.

The following is a more detailed description according to the LED package structure 1 of the illustrated embodiment of FIG. 1.

The transparent protective shield 13 comprises a supporting wall 131 and a top portion 132. The supporting wall 131 is disposed on the carrier surface 110 of the substrate 11, and surrounding the light-emitting chip 12. The top portion 132 of the transparent protective shield 13 is disposed on the supporting wall 131 and covering the light-emitting chip 12. In this embodiment, the upper surface of the top portion 132 of the transparent protective shield 13 can be, for example, a plane (or planar surface), but the present invention is not limited by this example.

Noticeably, the supporting wall 131 and the top portion 132 of the transparent protective shield 13 can be, for example, a primary molding structure, but the present invention is not limited by this example. In the other embodiment, the supporting wall 131 and the top portion 132 can be, for example, a plurality of independent discrete elements respectively. In other words, the transparent protective shield 13 can be made by combining together a plurality of independent discrete elements such as the supporting wall 131 and the top portion 132, or made in an integral unitary molded structure.

The substrate 11 further comprises a plurality of conductive pads 111nd 112. The light-emitting chip 12 has a first electrical connecting portion 121 and a second electrical connecting portion 122. In this first embodiment, the first electrical connecting portion 121 is opposite to the second electrical connecting portion 122. The first electrical connecting portion 121 defines an electrode (not shown) for electrically connecting to the conductive pad 111 of the substrate 11. The second electrical connecting portion 122 defines the other electrode for electrically connecting to the conductive pad 112 of the substrate 11. More specifically, the second electrical connecting portion 122 is, for example, electrically connecting to the conductive pad 112 by means of the electrical conductive line 14 of the LED package structure 1. However, the electrical connecting structure between the light-emitting chip 12 and the substrate 11 is only an example in this illustrated embodiment. The present invention is not limited by this first example/embodiment. The electrical connecting structure between the light-emitting chip 12 and the substrate 11 can be modified according to different situations. For example, two electrodes of the light-emitting chip can be electrically connecting to two conductive pads of the substrate 11 by means of the electrical conductive line 14 respectively. Moreover, the light-emitting chip 12 is correspondingly disposed on, for example, the center of the top portion 132 of the transparent protective shield 13. Besides, in this embodiment, the conductive pads 111, 112 penetrate, for example, the substrate 11. However, the present invention is not limited by this example. In the other embodiment, the conductive pads 111, 112 do not penetrate the substrate 11.

In this embodiment, the material of the transparent protective shield 13 can be, for example, glass, acrylic, crystal, Aluminium Oxide or Zirconium Oxide. However, the embodiment is not limited by these materials.

Noticeably, for the purpose of promoting the heat dissipation of the LED package structure 1, in the embodiment, the hermetic receiving space S of the LED package structure 1 can be filled with inert gas such as Helium (He), Neon (Ne), Argon (Ar), Krypton (Kr), Xenon (Xe) or Radon (Rn) to promote the heat dissipation of the LED package structure 1.

The LED package structure 1 of the embodiment is using a transparent protective shield 13 molded in advance to replace the conventional package element formed by means of encapsulation process. Different from the conventional package element, the transparent protective shield 13 of the present invention can choose the package material with better mechanical characters or properties. Therefore, the LED package structure 1 of the first embodiment of present invention has a better mechanical strength, and can avoid the disadvantages of insufficient mechanical strength and prevent the material of the transparent protective shield 13 from aging owing or due to light illumination and the refraction deterioration.

For the purpose of meeting various laminating requirements, the shapes of the transparent protective shield 13 can be changed to adjust the light beam types of the LED package structure 1. The following will describe in detail of a plurality of LED package structures according to different embodiments of present invention. These LED package structures have different light beam types respectively.

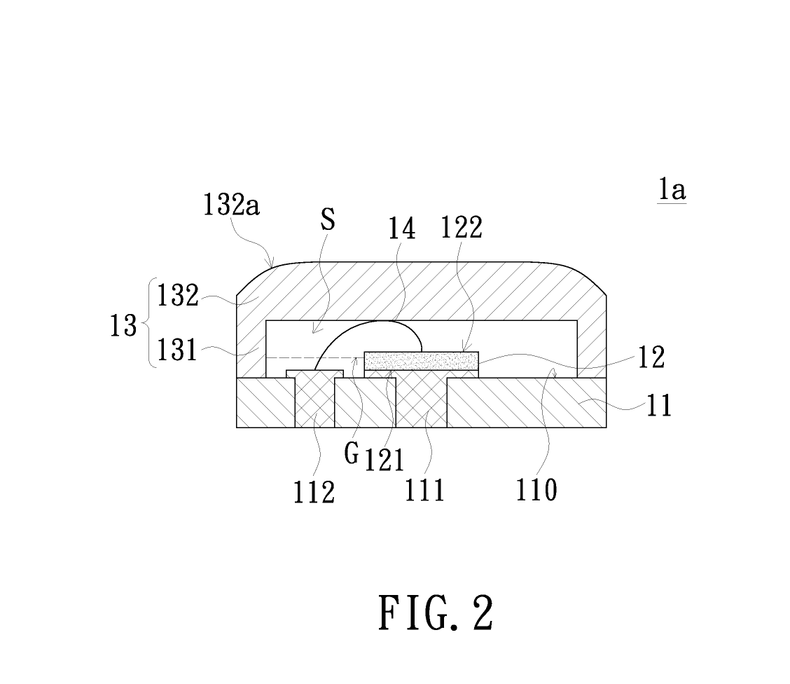

Referring to FIG. 2, in this second embodiment, the LED package structure 1a is similar to the LED package structure 1 shown in FIG. 1. The difference between the two embodiments lies in the shape of the surface of the top portion of the transparent protective shield. In this second embodiment, the upper surface of the top portion 132a is, for example, a curved surface.

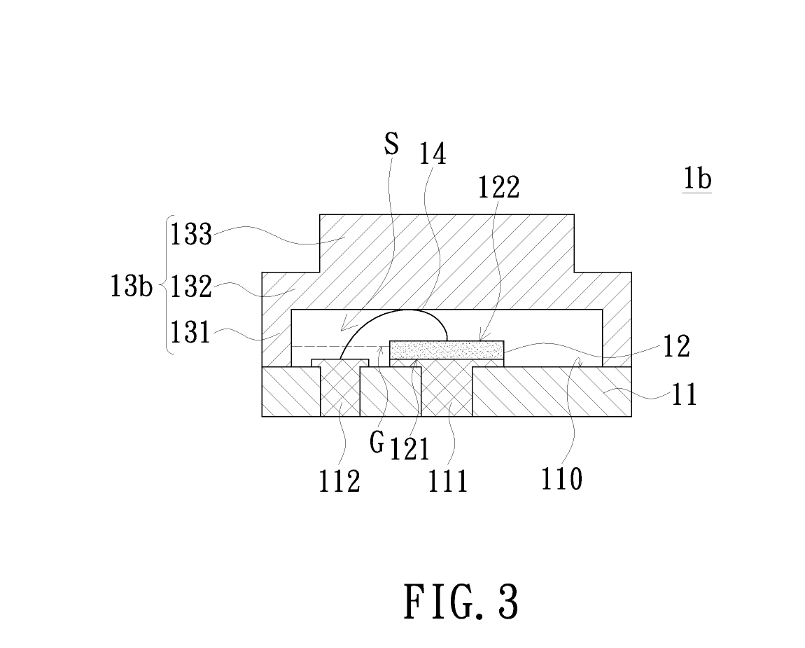

Referring to FIG. 3, the LED package structure 1b of a third embodiment as shown in FIG. 3 is similar to the LED package structure 1 shown in FIG. 1. The difference between the two embodiments lies in that the transparent protective shield 13b of the third embodiment comprises the supporting wall 131, the top portion 132 and a first stack portion 133 disposed on the top portion 132. The first stack portion 133 is disposed on the center of the top portion 132.

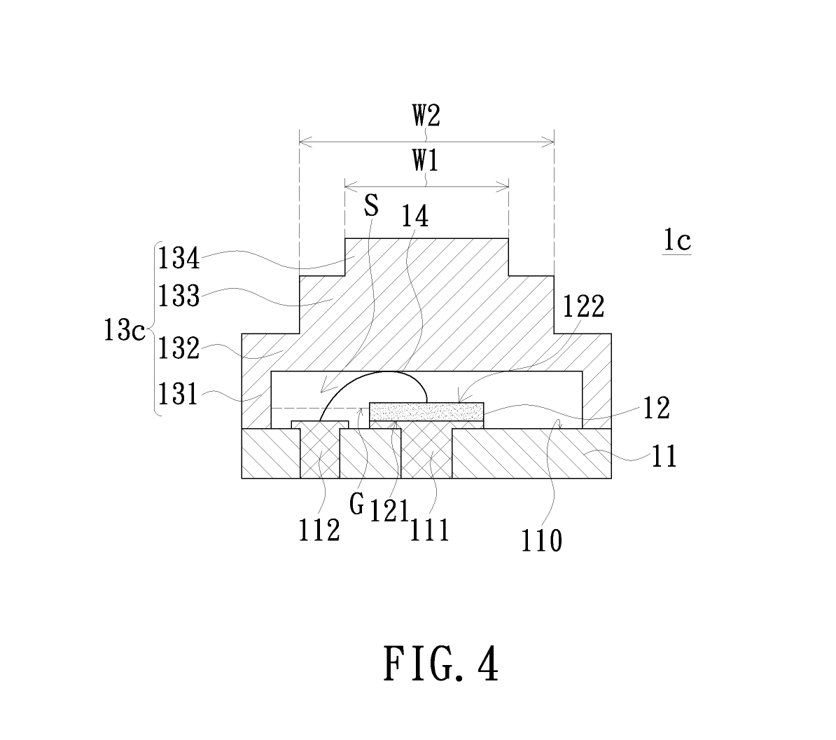

Referring to FIG. 4, the LED package structure 1c of the fourth embodiment is similar to the LED package structure 1b of the third embodiment shown in FIG. 3. The difference lies in that the transparent protective shield 13c comprises the supporting wall 131, the top portion 132, the first stack portion 133 and a second stack portion 134. The first stack portion 133 is disposed on the top portion 132. The second stack portion 134 is disposed on the first stack portion 133. In this illustrated embodiment, a width W1 of the second stack portion 134 is smaller than a width W2 of the first stack portion 133. The first stack portion 133 is disposed on the center of the top portion 132. The second stack portion 134 is disposed on the center of the first stack portion 133.

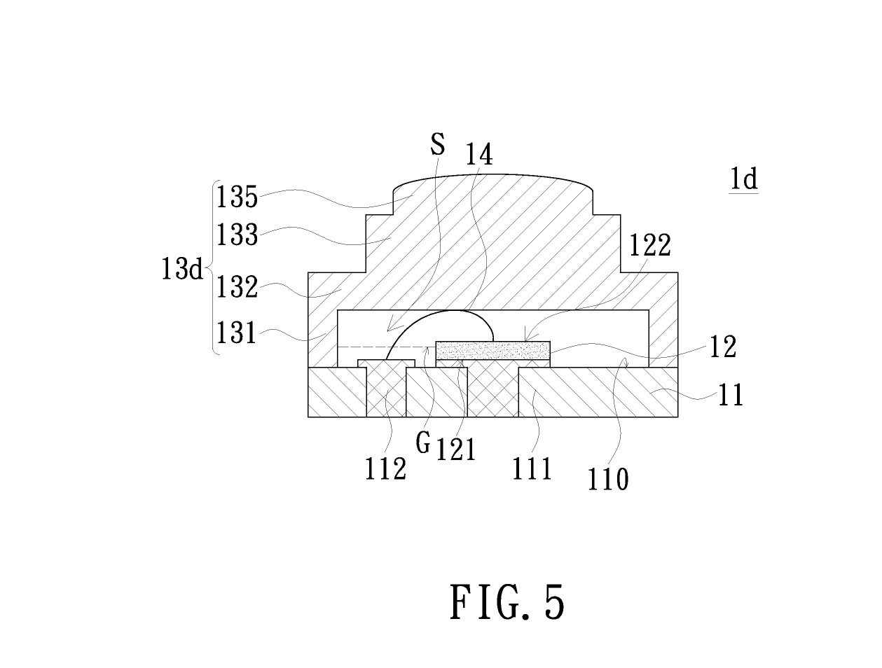

Referring to FIG. 5, the LED package structure 1d of a fifth embodiment is similar to the LED package structure 1b shown in FIG. 3. The difference lies in that the transparent protective shield 13d of the fifth embodiment comprises the supporting wall 131, the top portion 132, the first stack portion 133 and a lens 135. The first stack portion 133 is disposed on the top portion 132. The lens 135 is disposed on the first stack portion 133. The first stack portion 133 is disposed on the center of the top portion 132. The lens 135 is disposed on the center of the first stack portion 133. In this illustrated embodiment, the lens 135 is a convex lens for focusing the light beam emitted from the light-emitting chip 12. However, the present invention is not limited by this example/embodiment. For example, in other embodiment, the lens 135 can be a concave lens to diverge the light beam emitted from the light-emitting chip 12.

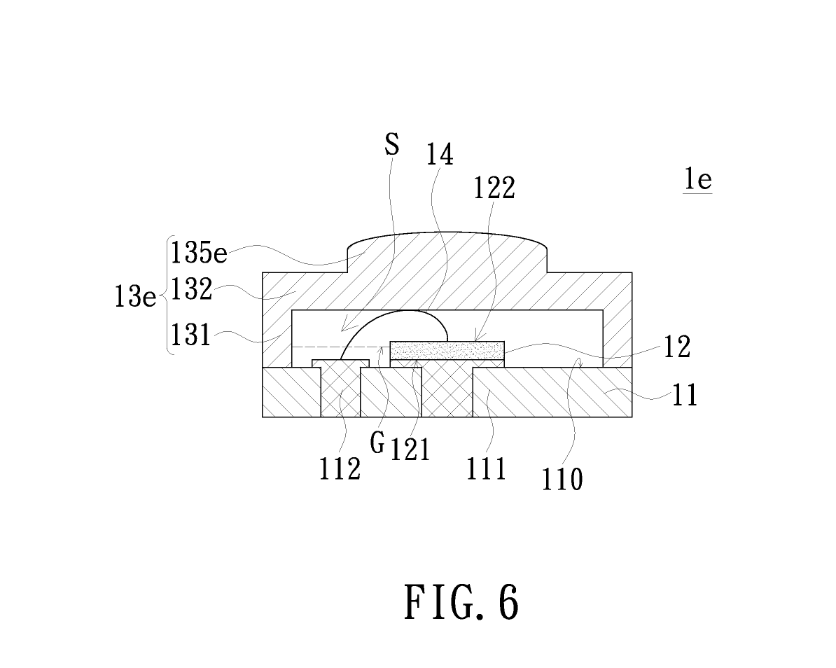

Referring to FIG. 6, the LED package structure 1e of a sixth embodiment is similar to the LED package structure 1 shown in FIG. 1. The difference lies in that the transparent protective shield 13e comprises the supporting wall 131, the top portion 132 and the lens 135e disposed on the top portion 132. The lens 135e is disposed on the center of the top portion 132. In this illustrated embodiment, the lens 135e is a convex lens to diverge the light beam emitted from the light-emitting chip 120. However, the present invention is not limited by this example/embodiment. For example, in other embodiment, the lens 135e can be a concave lens to diverge the light beam emitted from the light-emitting chip 12.

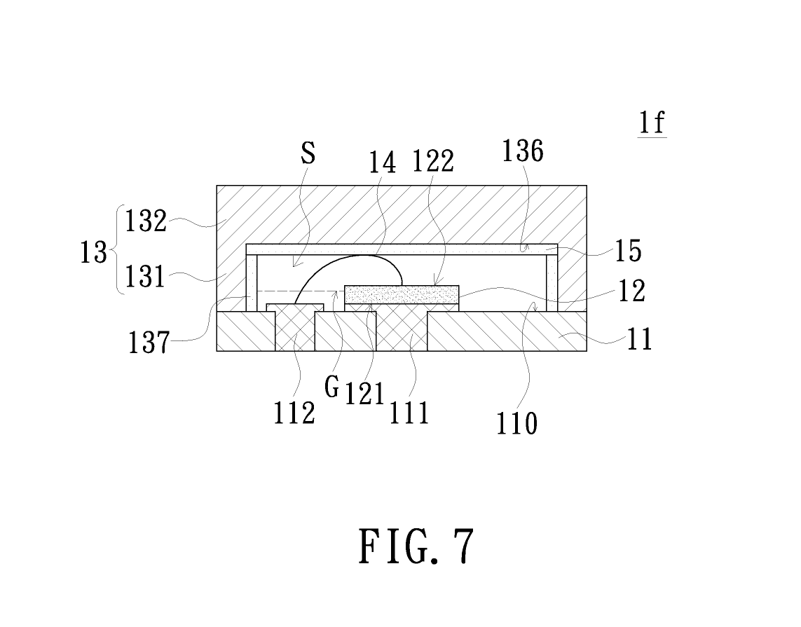

Referring to FIG. 7, the LED package structure 1f of a seventh embodiment is similar to the LED package structure 1 shown in FIG. 1. The difference lies in that the LED package structure 1f further comprises a phosphor layer 15 coated on the interior surface of the transparent protective shield 13. In this illustrated embodiment, the phosphor layer 15 is coated on the surface 136 of the transparent protective shield 13, the surface 136 is facing to the light-emitting chip 12 and disposed above the light-emitting chip 12. However, the present invention is not limited by this example/embodiment. In other embodiment, the phosphor layer 15 completely covers the surface 136 of the transparent protective shield 13 and the side wall 137 adjacent to the surface 136. Besides, the thickness of the phosphor layer 15 coated on the transparent protective shield 13 is from 10 micrometers to 20 micrometers.

The effect of coating the phosphor layer 15 onto the transparent protective shield 13 lies in transferring a part of the light beam emitted from the light-emitting chip 12 to be of a specific color light beam, further mixing with the original light beam. For example, the light-emitting chip 12 emits blue light beam, the phosphor layer 15 is yellow phosphor layer (for example, YAG phosphor layer). When the blue light beam passes through the phosphor layer 15, the blue light beam emitted from the light-emitting chip 12 will activate the phosphor layer 15 to emit yellow light beam, so as to make the blue light beam emitted from the light-emitting chip 12 mix with the yellow light beam and become a white light beam. Besides, the phosphor layer 15 also can be applied to the LED package structure of the above embodiment.

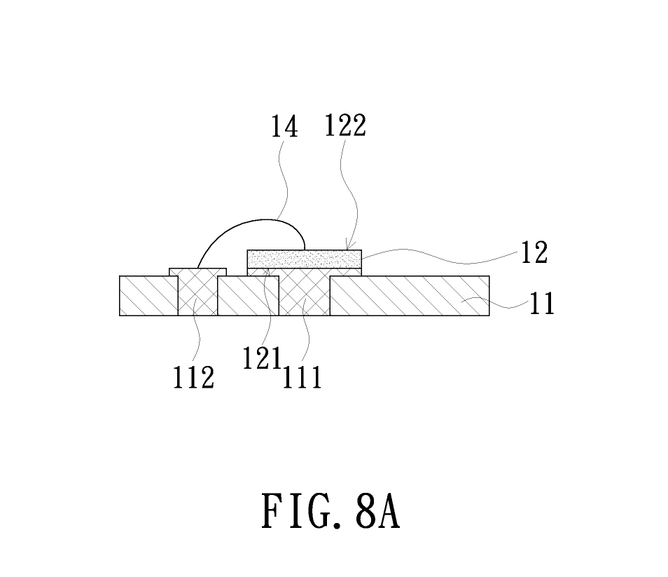

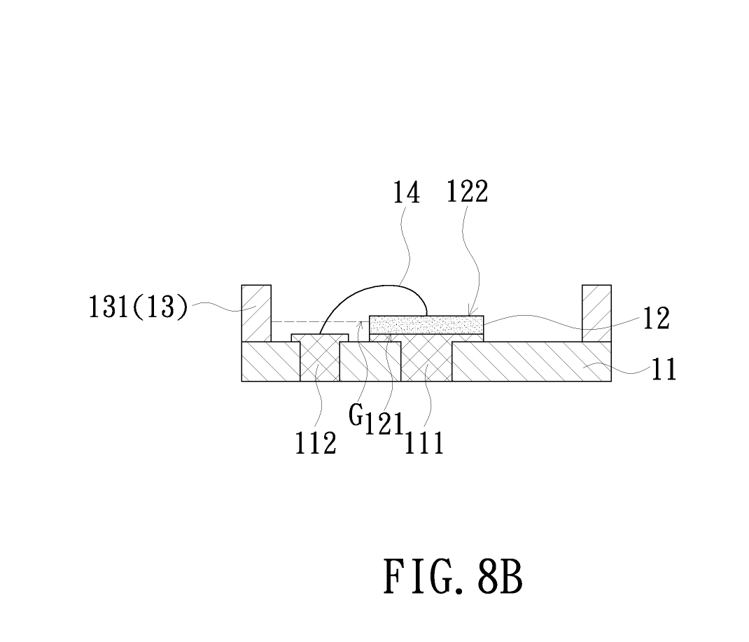

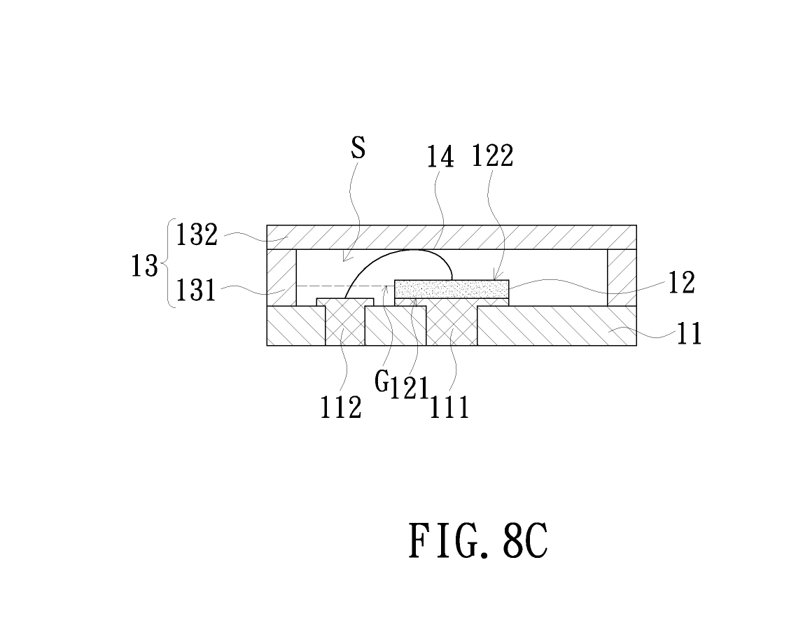

Referring to FIG. 8A to FIG. 8C, showing the process diagrams for a LED package structure manufacturing method of an embodiment of the present invention. More particularly, the LED package structure by means of the manufacturing method of the embodiment (shown in FIG. 8C) is similar to the LED package structure shown in FIG. 1. Therefore, the element numbers of FIG. 8A to FIG. 8C are the same with the element numbers of FIG. 1.

Firstly, Referring to FIG. 8A, the light-emitting chip 12 is disposed on the carrier surface 110 of the substrate 11 and electrically connecting to the substrate 11. More specifically, the electrode (not shown) of the first electrical connecting portion 121 of the light-emitting chip 12 is electrically connecting to the conductive pad 111 of the substrate 11. The electrode (not shown) of the second electrical connecting portion 122 of the light-emitting chip 12 is electrically connecting to the conductive pad 112 of the substrate 11. The electrode of the second electrical connecting portion 122 is electrically connecting to the conductive pad 112 by means of the electrical conductive line 14.

Then, as shown in FIG. 8B, by means of colloid (not shown), for example an optical curing adhesive, a supporting wall 131 of the transparent protective shield 13 can be bonded on the carrier surface 110 of the substrate 11, and make the supporting wall 131 surround the light-emitting chip 12.

Referring to FIG. 8C, by means of colloid (not shown), for example the optical curing adhesive, the top portion 132 of the transparent protective shield 13 is bonded to the supporting wall 131, and covers the light-emitting chip 12, so as to form a hermetic receiving space S between the transparent protective shield 13 and the substrate 11. The light-emitting chip 12 is located in the hermetic receiving space S. A gap G is formed between the light-emitting chip 12 and the transparent protective shield 13.

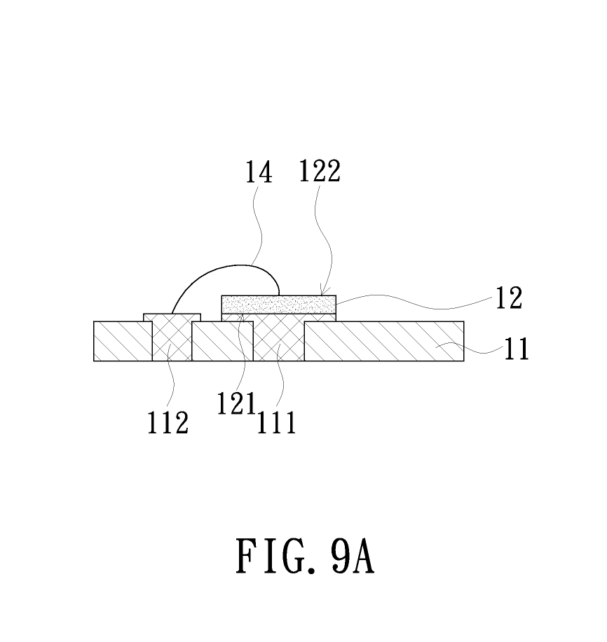

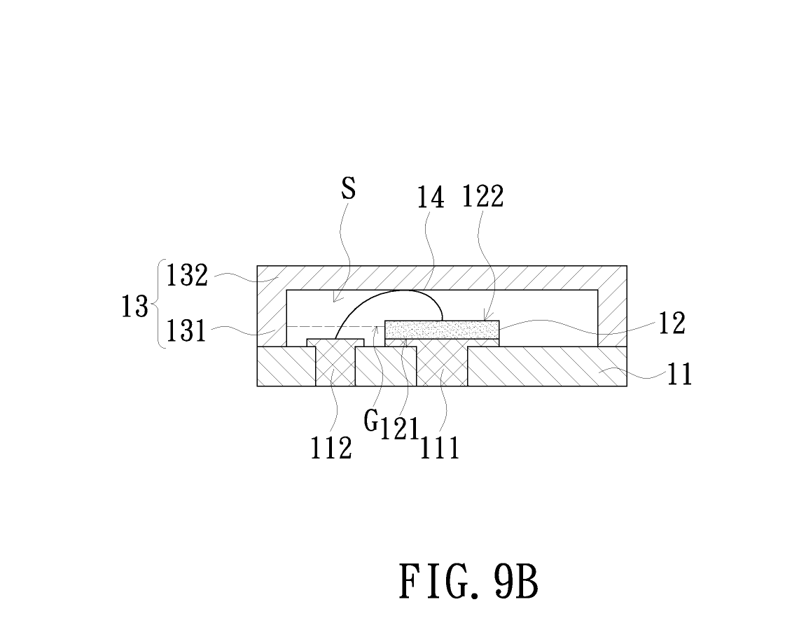

Referring to FIG. 9A to FIG. 9B, showing the process diagrams of the LED package structure manufacturing method. More particularly, the LED package structure (shown in FIG. 9) by means of the embodiment is similar to the LED package structure shown in FIG. 1. Therefore, the element numbers of FIG. 9A to FIG. 9B are the same with the element numbers of FIG. 1.

Firstly, as shown in FIG. 9A, a light-emitting chip 12 is disposed on the carrier surface 110 of the substrate 11. The light-emitting chip 12 is electrically connecting to the substrate 11. More specifically, the electrode (not shown) of the first electrical connecting portion 121 on the light-emitting chip 12 is electrically connecting to the conductive pad 111 of the substrate 11. The electrode (not shown) of the second electrical connecting portion 122 on the light-emitting chip 12 is electrically connecting to the conductive pad 112 of the substrate 11. The electrode (not shown) of the second electrical connecting portion 122 is electrically connecting to the conductive pad 112 by means of the electrical conductive line 14.

Then, as shown in FIG. 9B, by means of colloid (for example, an optical curing adhesive), the supporting wall 131, the top portion 132 and an integrally-molded (unitary) transparent protective shield 13 are bonded on the carrier surface 110 of the substrate 11, so as to adhere and mount the supporting wall 131 onto the carrier surface 110 of the substrate 11. The supporting wall 131 is disposed to surround the light-emitting chip 12, and make the top portion 132 cover the light-emitting chip 12. The integrally-molded transparent protective shield 13 is bonded onto the carrier surface 110 of the substrate 11, and then a hermetic receiving space S can be formed between the transparent protective shield 13 and the substrate 11. The light-emitting chip 12 is located in the hermetic receiving space S. A gap G is formed between the light-emitting chip 12 and the transparent protective shield 13.

Noticeably, the manufacturing method of the above embodiments can be applied to a vacuum environment. Furthermore, inert gas can be filled into the vacuum environment. Then the hermetic receiving space S can be filled with inert gas, it is beneficial for heat dissipation. Besides, the above embodiments take one single LED package structure as an example, however, in the other embodiment, a plurality of light-emitting chips 12 can be processed by the package process in the same time. After finishing the procedure of FIG. 8C, the cutting process can be performed to cut the substrate 11 and the transparent protective shield 13 to make a plurality of individual LED package structures. In addition, the method of bonding the transparent protective shield of the LED package structure to the substrate as shown in FIG. 2 to FIG. 7 are, the same with the manufacturing method shown in FIG. 8A to FIG. 8C or the manufacturing method shown in FIG. 9A to FIG. 9B.

In summary, the LED package structures of the embodiments of present invention is using a transparent protective shield molded in advance to replace the conventional package element formed by means of encapsulation process. Different from the conventional package element, the transparent protective shield of the embodiments of present invention can choose the package material of better mechanical characters/properties. Therefore, the LED package structure of the present invention has a better mechanical strength, and can avoid the disadvantages of insufficient mechanical strength and prevent the material of the transparent protective shield from aging caused by light illumination and the refraction deterioration.

The foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

What is claimed is:

1. A LED package structure comprising:
a substrate having a carrier surface;
a light-emitting chip disposed on the carrier surface of the substrate, electrically connecting to the substrate; and
a transparent protective shield disposed on the carrier surface of the substrate,
wherein a hermetic receiving space is formed between the transparent protective shield and the substrate, the light-emitting chip is disposed in the hermetic receiving space, a gap is formed between the light-emitting chip and the transparent protective shield.

2. The LED package structure as claimed in claim 1, wherein the transparent protective shield comprising a supporting wall disposed on the carrier surface of the substrate and surrounding the light-emitting chip, and a top portion disposed on the supporting wall and covering the light-emitting chip.

3. The LED package structure as claimed in claim 2, wherein an upper surface of the top portion is a plane or a curved surface.

4. The LED package structure as claimed in claim 2, wherein the transparent protective shield further comprising a first stack portion disposed on the top portion of the transparent protective shield.

5. The LED package structure as claimed in claim 4, wherein the transparent protective shield further comprising a second stack portion disposed on the first stack portion, a width of the second stack portion is smaller than a width of the first stack portion.

6. The LED package structure as claimed in claim 4, wherein the transparent protective shield further comprising a lens disposed on the first stack portion.

7. The LED package structure as claimed in claim 2, wherein the transparent protective shield further comprising a lens disposed on the top portion.

8. The LED package structure as claimed in claim 2, wherein the transparent protective shield is an integrally-molded structure.

9. The LED package structure as claimed in claim 3, wherein the transparent protective shield is an integrally-molded structure.

10. The LED package structure as claimed in claim 4, wherein the transparent protective shield is an integrally-molded structure.

11. The LED package structure as claimed in claim 5, wherein the transparent protective shield is an integrally-molded structure.

12. The LED package structure as claimed in claim 6, wherein the transparent protective shield is an integrally-molded structure.

13. The LED package structure as claimed in claim 7, wherein the transparent protective shield is an integrally-molded structure.

14. The LED package structure as claimed in claim 1, wherein the material of the transparent protective shield is glass, acrylic, crystal, Aluminium Oxide, or Zirconium Oxide.

15. The LED package structure as claimed in claim 1, wherein further comprising an inert gas filled in the hermetic receiving space.

16. The LED package structure as claimed in claim 1, wherein further comprising a phosphor layer coated at least on a side of the transparent protective shield facing the light-emitting chip and disposed on the surface of the transparent protective shield located above the light-emitting chip.

17. A LED package structure manufacturing method, comprising the steps of:
disposing a light-emitting chip on a carrier surface of a substrate, and electrically connecting the light-emitting chip to the substrate;
disposing a transparent protective shield on the carrier surface of the substrate,
wherein a hermetic receiving space is formed between the transparent protective shield and the substrate, the light-emitting chip is disposed in the hermetic receiving space, a gap is formed between the light-emitting chip and the transparent protective shield.

18. The manufacturing method as claimed in claim 17, wherein the transparent protective shield comprising a supporting wall and a top portion, the step of disposing a transparent protective shield on the carrier surface of the substrate further comprising:
bonding the supporting wall on the carrier surface of the substrate by means of an optical light-sensitive adhesive and surrounding the light-emitting chip, and
bonding the top portion on the supporting wall by means of the optical light-sensitive adhesive and covering the light-emitting chip.

19. The manufacturing method as claimed in claim 17, wherein the transparent protective shield comprising a supporting wall and a top portion, the protective shield is integrally-molded, the step of disposing a transparent protective shield on the carrier surface of the substrate further comprising:
bonding the supporting wall on the carrier surface of the substrate by means of an optical curing adhesive and surrounding the light-emitting chip, and the top portion covers the light-emitting chip.
